(19) United States
(12) Patent Application Publication
(10) Pub. No.: US 2024/0119190 A1
(43) Pub. Date: Apr. 11, 2024

(54) EVALUATION APPARATUS, EVALUATION METHOD, AND COMPUTER READABLE MEDIUM

(71) Applicant: Mitsubishi Electric Corporation, Tokyo (JP)

(72) Inventors: Jin Kawasaki, Tokyo (JP); Shinichiro Otani, Tokyo (JP); Risa Murakami, Tokyo (JP); Yoshihiro Ohta, Tokyo (JP); Masanori Hashimoto, Tokyo (JP)

(73) Assignee: Mitsubishi Electric Corporation, Tokyo (JP)

(21) Appl. No.: 18/540,018

(22) Filed: Dec. 14, 2023

Related U.S. Application Data
(63) Continuation of application No. PCT/JP2021/028839, filed on Aug. 3, 2021.

(51) Int. Cl. G06F 30/13; G06Q 10/04

(52) U.S. Cl. CPC G06F 30/13; G06Q 10/04

(57) ABSTRACT

An area evaluation unit (51) acquires for each area of a plurality of areas, a predictive value of each area which is predicted to be measured when a device operates in a space that includes the plurality of areas. A building evaluation unit (52) acquires an overall predictive value which is a predictive value of the entire space calculated using a plurality of predictive values of the plurality of areas. Further, the area evaluation unit (51) evaluates the predictive value of each area, using a partial evaluation criterion which is an evaluation criterion applied to each area. Further, the building evaluation unit (52) evaluates the overall predictive value, using an overall evaluation criterion which is an evaluation criterion applied to the entire space.

### CROSS REFERENCE TO RELATED APPLICATIONS

This application is a Continuation of PCT International Application No. PCT/JP2021/028839, filed on Aug. 3, 2021, which is hereby expressly incorporated by reference into the present application.

### TECHNICAL FIELD

The present disclosure relates to a technique to evaluate performance of a device installed in a space.

### BACKGROUND ART

As a conventional device control design technique, there is, for example, the technique described in Patent Literature 1. The technique of Patent Literature 1 predicts a control result of comfortability for each area in a building, and controls a device so that the comfortability becomes closer to a state of a target value set for each area.

### CITATION LIST

### Patent Literature

Patent Literature 1: JP 2020-060338 A

### SUMMARY OF INVENTION

### Technical Problem

On the other hand, in a recent office building, both of a target value of the entire building and a target value of each area in the building are set, and it is expected to control a device so that both of those are satisfied. For example, for the entire building, target values of energy and comfortability for achieving a net Zero Energy Building (“ZEB”) are set as requested by an owner of the building. For each area in the building, target values of energy and comfortability are set as requested by a tenant of the area.

In the technique of Patent Literature 1, it is possible to evaluate for each area, whether or not the target value is achieved. However, in the technique of Patent Literature 1, it is not evaluated whether or not the target value of the entire building is achieved. Therefore, the technique of Patent Literature 1 has a problem of being unable to clarify whether or not the target value of the entire building is achieved.

The present disclosure mainly aims to solve a problem such as above. More specifically, the present disclosure mainly aims to enable evaluation of a device in terms of each area and evaluation of a device in terms of an entire space that includes a plurality of areas.

### Solution to Problem

An evaluation apparatus according to the present disclosure includes:
a first predictive value acquisition unit to acquire for each area of a plurality of areas, a predictive value of each area, which is predicted to be measured when a device operates in a space that includes the plurality of areas;
a second predictive value acquisition unit to acquire an overall predictive value which is a predictive value of the entire space calculated using a plurality of predictive values of the plurality of areas;
a first evaluation unit to evaluate the predictive value of each area acquired by the first predictive value acquisition unit, using a partial evaluation criterion which is an evaluation criterion applied to each area; and
a second evaluation unit to evaluate the overall predictive value acquired by the second predictive value acquisition unit, using an overall evaluation criterion which is an evaluation criterion applied to the entire space.

### Advantageous Effects of Invention

According to the present disclosure, evaluation of a device in terms of each area and evaluation of a device in terms of an entire space are possible.

### BRIEF DESCRIPTION OF DRAWINGS

FIG. 1 is a diagram illustrating a configuration example of a device control design system according to Embodiment 1.

FIG. 2 is a diagram illustrating a functional configuration example of a device control design apparatus according to Embodiment 1.

FIG. 3 is a diagram illustrating a functional configuration example of the device control design apparatus according to Embodiment 1.

FIG. 4 is a diagram illustrating an example of area usage purpose information according to Embodiment 1.

FIG. 5 is a diagram illustrating an example of layout information according to Embodiment 1.

FIG. 6 is a diagram illustrating an example of an area evaluation expression according to Embodiment 1.

FIG. 7 is a diagram illustrating a hardware configuration example of the device control design apparatus according to Embodiment 1.

FIG. 8 is a flowchart illustrating an operational example of the device control design apparatus according to Embodiment 1

FIG. 9 is a diagram illustrating a functional configuration example of the device control design apparatus according to Embodiment 2.

FIG. 10 is a diagram illustrating an example of conversion rule information according to Embodiment 2.

FIG. 11 is a diagram illustrating a functional configuration example of the device control design apparatus according to Embodiment 3.

FIG. 12 is a diagram illustrating an example of device management information according to Embodiment 3.

FIG. 13 is a diagram illustrating a functional configuration example of the device control design apparatus according to Embodiment 4

FIG. 14 is a diagram illustrating a functional configuration example of the device control design apparatus according to Embodiment 5

FIG. 15 is a diagram illustrating a functional configuration example of the device control design apparatus according to Embodiment 6.

FIG. 16 is a diagram illustrating a functional configuration example of the device control design apparatus according to Embodiment 7.

FIG. 17 is a diagram illustrating a functional configuration example of the device control design apparatus according to Embodiment 8.

### DESCRIPTION OF EMBODIMENTS

Embodiments will be described hereinafter with reference to the drawings. In the following description of the embodiments and the drawings, portions denoted by the same reference signs indicate the same or corresponding portions.

### Embodiment 1

***Overview***

A device control design apparatus will be described in the present embodiment.

The device control design apparatus according to the present embodiment evaluates performance of a device that acts on a space that includes a plurality of areas.

In the present embodiment, a building that includes a plurality of floors (story floors) will be described as an example of the space. However, one floor or the plurality of floors in the building may be treated as the space. Alternatively, a part of one floor may be treated as the space.

An area is a region obtained by dividing the space. When the entire building is the space, the area is, for example, each floor or a room provided on each floor. Alternatively, when the plurality of floors is the space, the area is, for example, each floor or a room provided on each floor. Alternatively, when one entire floor or a part of one floor is the space, the area is a room provided on the floor.

Further, the device may be installed inside the building or outside the building. Further, “acting on a space” means changing a physical amount to be measured in the space. The physical amount is, for example, an environmental value such as temperature, humidity, air volume, CO₂ concentration, illuminance, or the like in the space. The device is, for example, an air conditioner, a ventilation device, a lighting device, or the like.

In the present embodiment, the device control design apparatus predicts for each area, a measurement value when the device operates in the building. A value obtained by the prediction is referred to as a predictive value. The device control design apparatus predicts as predictive values, for example, an energy value and an environmental value. Further, the device control design apparatus calculates the predictive value of the entire building based on a plurality of predictive values of a plurality of areas. The predictive value of the entire building is referred to as an overall predictive value.

Further, the device control design apparatus evaluates the predictive value of each area, using an evaluation criterion applied to each area. Further, the device control design apparatus evaluates the overall predictive value, using an evaluation criterion applied to the entire building.

Then, the device control design apparatus presents a control designer (for example, a system engineer) who performs a device control design, with an evaluation result of each area and an evaluation result of the entire building.

As a result, the control designer can comprehensively analyze the evaluation result of each area and the evaluation result of the entire building, and decide a control parameter for controlling the device.

***Description of Configuration***

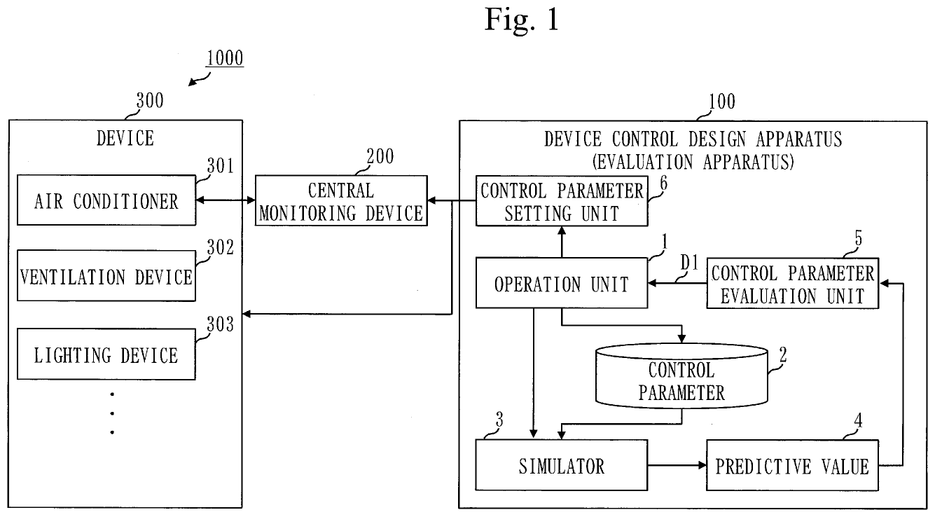

FIG. 1 illustrates a configuration example of a device control design system 1000 according to the present embodiment.

The device control design system 1000 is configured with a device control design apparatus 100, a central monitoring device 200, and a device 300.

The device 300 is a device that acts on a building.

FIG. 1 illustrates an air conditioner 301, a ventilation device 302, and a lightning device 303, as the device 300. These air conditioner 301, ventilation device 302, and lightning device 303 are examples, and a device other than these may be provided. Alternatively, only a part of these devices may be provided. Alternatively, a plurality of each of the air conditioner 301, the ventilation device 302, and the lightning device 303 may be provided.

When there is no need to distinguish between the air conditioner 301, the ventilation device 302, and the lightning device 303, these are hereinafter simply referred to as the device 300.

The central monitoring device 200 controls the device 300, using a control parameter 2.

The device control design apparatus 100 notifies the central monitoring device 200 of the control parameter 2 decided by a control designer.

The control designer is a person who uses the device control design apparatus 100. The control designer is, for example, an engineer (a device control designer, a construction engineer, a system engineer, or the like) who is in charge of practical works at a business operator such as a vendor, a subcontractor, a design office, or a Sler of the device 300. Further, control designers may include an owner of the building, a tenant of an area, and a manager of the building.

The device control design apparatus 100 accepts operation of the control designer, and performs the calculation of the predictive value of each area, the calculation of the overall predictive value, the evaluation of performance of the device 300 in terms of each area, and the evaluation of performance of the device 300 in terms of the entire building, as described above.

[Description of Individual Configuration Components]

The device control design apparatus 100 includes an operation unit 1, the control parameter 2, a simulator 3, a predictive value 4, a control parameter evaluation unit 5, and a control parameter setting unit 6.

The device control design apparatus 100 is equivalent to an evaluation apparatus. Further, an operational procedure of the device control design apparatus 100 is equivalent to an evaluation method. Further, a program that implements operation of the device control design apparatus 100 is equivalent to an evaluation program.

The individual configuration components of the device control design apparatus 100 will be described below.

(Operation Unit 1)

The operation unit 1 sets the control parameter 2 by operation of the control designer. Further, the operation unit 1 executes the simulator 3, using the control parameter 2, and receives an evaluation result D1 which is output of the control parameter evaluation unit 5.

The operation unit 1 presents the control designer with the evaluation result D1.

When there is no problem with the evaluation result D1, the control designer performs operation to select the control parameter 2 as a control parameter to be set to the device 300.

On the other hand, when there is a problem with the evaluation result D1, the control designer performs operation on the operation unit 1, to set a new control parameter 2. The operation unit 1 executes the simulator 3, using the new control parameter 2. Then, the operation unit 1 receives the evaluation result D1 regarding the new control parameter 2

The control designer repeats the above operation until the evaluation result D1 without any problem is obtained or another termination condition is satisfied.

The operation unit 1 outputs to the control parameter setting unit 6, the control parameter 2 selected by the control designer.

(Control Parameter 2)

The control parameter 2 is a candidate for a control value for controlling the device 300. The control parameter 2 is equivalent to a control value candidate.

The control parameter 2 is, for example, a parameter for point setting, schedule setting, and coalition setting.

A parameter for point setting is identification information, an Identifier (ID), an address, or the like for specifying the device 300 subject to activation or suspension. The parameter for point setting may be any information that can uniquely specify the device 300 subject to activation or suspension. The parameter for point setting is, for example, information that specifies the air conditioner 301 subject to activation or suspension.

Further, a parameter for schedule setting is information for specifying particular operation to be performed by the device 300 and a timing to cause the device 300 to perform the operation. The parameter for schedule setting is, for example, information that specifies operation of controlling a ventilation amount of the ventilation device 302 to a low level, and specifies a timing (information relating to a time such as date and time, time point, day of week, cycle, or the like) to cause the ventilation device 302 to perform the operation.

Furthermore, a parameter for coalition setting is information for specifying two or more devices 300 that operate in coalition with each other, and specifying operation to be performed by the two or more devices 300. The parameter for coalition setting is, for example, information that specifies operation of activating the lightning device 303 and the air conditioner 301 one after another, and specifies the lightning device 303 and the air conditioner 301.

The control parameter 2 is stored into a main storage device 102 or a hard disk 105 to be described below.

(Simulator 3)

The simulator 3 predicts a measurement value to be measured when the device 300 operates according to the control parameter 2. Then, the simulator 3 outputs the measurement value acquired by the prediction, as the predictive value 4, to the control parameter evaluation unit 5.

Here, measurement values are an energy value and an environmental value acquired when the device 300 operates according to the control parameter 2. The simulator 3 uses a model to be described below for predicting the measurement value.

The simulator 3 generates the predictive value for each area included in the building. Further, the simulator 3 generates the predictive value of the entire building (the overall predictive value) by aggregating the predictive value of each area. The simulator 3 outputs to the control parameter evaluation unit 5, the predictive value of each area and the predictive value of the entire building, as the predictive value 4.

(Predictive Value 4)

The predictive value 4 is a predicted measurement value output by the simulator 3. As described above, measurement values are an energy value and an environmental value acquired when the device 300 operates according to the control parameter 2. The energy value is, for example, electric power consumption of the device 300 when the device 300 is a demand device. Alternatively, the energy value may be electric power supply to the device 300. Alternatively, when the device 300 is an energy generation device, the energy value may be generated electric power by the device 300. Furthermore, when the device 300 is an energy accumulation device, the energy value may be accumulated electric power by the device 300.

The environmental value is, as described above, a value relating to environment such as temperature, humidity, air volume, CO₂ concentration, or illuminance in the building.

The predictive value 4 includes, as described above, the predictive value of each area and the predictive value of the entire building (the overall predictive value). The predictive value of each area is associated with an ID of an area. Further, the overall predictive value is associated with a building ID.

Further, the predictive value 4 may be the predictive value at a specific time, or temporal information on the predictive value in a prescribed time span (for example, ten minutes).

The predictive value 4 is stored into the main storage device 102 or the hard disk 105 to be described below.

(Control Parameter Evaluation Unit 5)

The control parameter evaluation unit 5 evaluates the predictive value 4 of each area, using an evaluation criterion (partial evaluation criterion) applied to each area. Further, the control parameter evaluation unit 5 evaluates the predictive value 4 of the entire building, using an evaluation criterion (overall evaluation criterion) applied to the entire building.

Then, the control parameter evaluation unit 5 outputs to the operation unit 1, an evaluation result of each area and an evaluation result of the entire building, as the evaluation result D1.

(Control Parameter Setting Unit 6)

When the control designer determines that there is no problem with the evaluation result D1 and selects the control parameter 2 as the control parameter to be set to the device 300, the control parameter setting unit 6 acquires the control parameter 2 from the operation unit 1.

Then, the control parameter setting unit 6 sets the control parameter 2 to the central monitoring device 200 and the device 300. The control parameter setting unit 6 may set the control parameter 2 only to the central monitoring device 200, or set the control parameter 2 only to the device 300. Alternatively, the control parameter setting unit 6 may set the control parameter 2 only to a part of the devices 300, for example, the air conditioner 301.

The control parameter setting unit 6 sets the control parameter 2, using interfaces with outside provided by each of the central monitoring device 200 and the device 300, such as a communication interface, an operation input interface, or the like. Further, when the central monitoring device 200 can set the control parameter 2 to the device 300, the control parameter setting unit 6 may perform the setting of the control parameter 2 to the device 300, via the interface of the central monitoring device 200.

In the present embodiment, it is premised that the device control design apparatus 100 is installed near the central monitoring device 200 and the device 300. However, the device control design apparatus 100 may be installed remotely from the central monitoring device 200 and the device 300. For example, a case is assumed where the device control design apparatus 100 is in a server device installed at a remote place from the building, and the central monitoring device 200 and the device 300 are inside the building. In this case, the server device and the building are connected via a communication network, and the device control design apparatus 100 sets the control parameter 2 to the central monitoring device 200 and the device 300 via the communication network.

Further, a case is assumed where the device control design apparatus 100 and the central monitoring device 200 are in a server device at a remote place from the building, and the device 300 is inside the building. In this case, the device control design apparatus 100 sets the control parameter 2 to the central monitoring device 200 through, for example, inter-process communication, and sets the control parameter 2 to the device 300 via the communication network.

The server device at the remote place may be located on any of a wide Local Area Network (LAN), a data center via the Internet, and a cloud network.

Furthermore, in the present embodiment, it is premised that the control parameter 2, the predictive value 4, and the evaluation result D1 are stored into the main storage device 102 or the hard disk 105 in the device control design apparatus 100, as described below. However, the control parameter 2, the predictive value 4, and the evaluation result D1 may be stored into a network storage device outside the device control design apparatus 100. In this case, the device control design apparatus 100 writes and reads the predictive value 4 and the evaluation result D1 via a network.

[Detailed Description of Configuration Components]

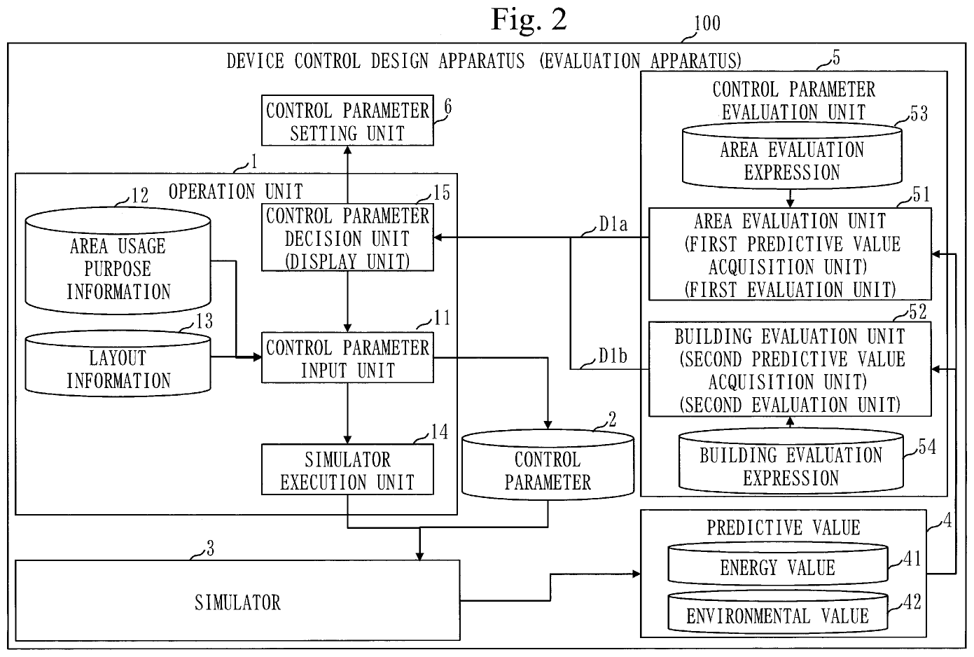

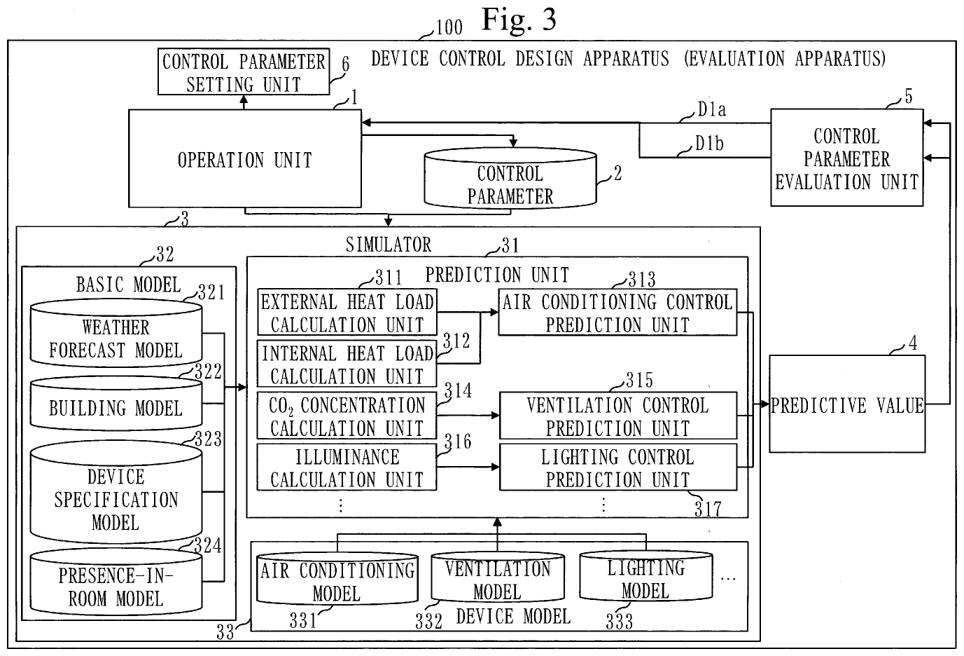

FIGS. 2 and 3 illustrate details of a functional configuration of the device control design apparatus 100.

FIG. 2 illustrates details of the operation unit 1, the predictive value 4, and the control parameter evaluation unit 5. FIG. 3 illustrates details of the simulator 3.

Details of the operation unit 1, the simulator 3, the predictive value 4, and the control parameter evaluation unit 5 will be described with reference to FIGS. 2 and 3.

(Operation Unit 1)

As illustrated in FIG. 2, the operation unit 1 includes a control parameter input unit 11, area usage purpose information 12, layout information 13, a simulator execution unit 14, and a control parameter decision unit 15.

Details of each will be described below.

(Control Parameter Input Unit 11)

The control parameter input unit 11 provides the control designer with a user interface for inputting the control parameter 2.

The control parameter input unit 11 reflects the area usage purpose information 12 and the layout information 13 on the user interface.

When the control designer completes the input of the control parameter 2 for each area in the building, the control parameter input unit 11 outputs to the simulator execution unit 14, an execution instruction to the simulator 3.

(Area Usage Purpose Information 12)

The area usage purpose information 12 is information indicating usage purpose of an area.

For example, an office area, a concentration area, a conference area, a relaxation area, or the like, is assumed as the usage purpose of the area.

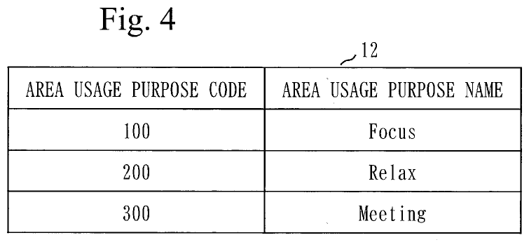

FIG. 4 illustrates an example of the area usage purpose information 12.

In FIG. 4, an area usage purpose code is a code that classifies area usage purpose.

Further, an area usage purpose name is a name that describes the area usage purpose corresponding to the area usage purpose code. In the example of FIG. 4, three area usage purpose s are defined, which are Focus (concentration area), Relax (relaxation area), and Meeting (conference area).

(Layout Information 13)

The layout information 13 is information indicating a position and a size of an area in the building. In the following, the position and the size of the area are collectively referred to as a layout of the area.

The layout information 13 represents the area, using, for example, Geographic Information System (GIS) coordinates. Therefore, the position and the size of the area can be obtained from the GIS coordinates indicated in the layout information 13. Further, the layout information 13 may be composed of an aggregation of vertex coordinates of the area, and adjacent situation information on the area. In this case, the layout of the area can be also obtained from the aggregation of vertex coordinates and the adjacent situation information indicated in the layout information 13.

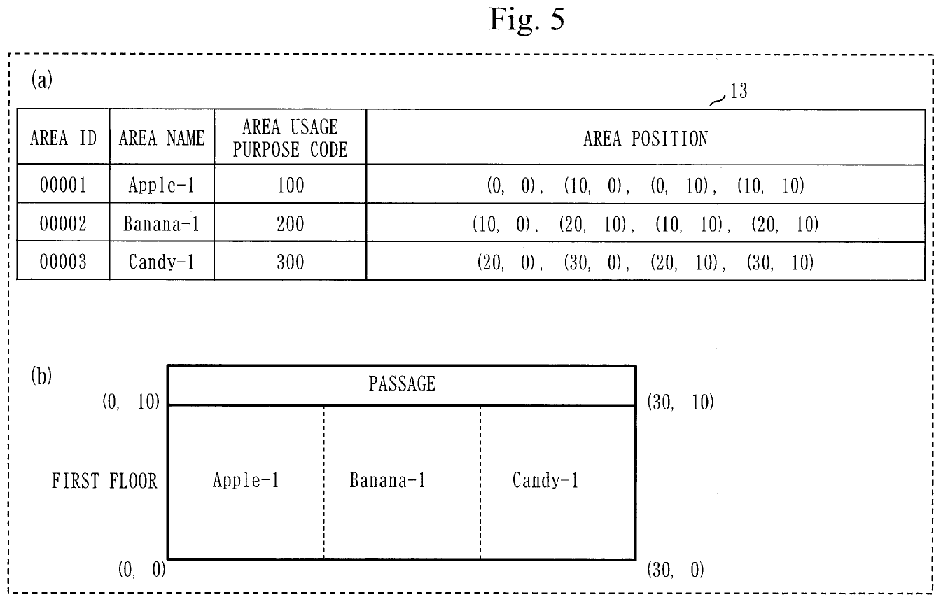

(a) of FIG. 5 illustrates an example of the layout information 13.

Further, (b) of FIG. 5 illustrates a layout of each area indicated in the layout information 13.

In (a) of FIG. 5, an area ID is an identifier that uniquely identifies an area. An area name is a name that describes an area. The area usage purpose code is a code that classifies area usage purposes, and is the same as that illustrated in FIG. 4. The area position is a coordinate value that represents the layout of the area. Although each area is defined two-dimensionally (rectangular) in FIG. 5, each area may be defined three-dimensionally. Note that (0, 0) means the origin.

(Simulator Execution Unit 14)

The simulator execution unit 14 executes the simulator 3 when the execution instruction is input from the control parameter input unit 11. The simulator execution unit 14 outputs the control parameter 2 to the simulator 3 at the execution of the simulator 3.

The simulator execution unit 14 may output the control parameter 2 to the simulator 3 by any method. The simulator execution unit 14 may store the control parameter 2 into a database accessible by the simulator 3. Further, the simulator execution unit 14 may output the control parameter 2 to the simulator 3, in a file format. The simulator execution unit 14 may output the control parameter 2 to the simulator 3 by other electronic means.

(Control Parameter Decision Unit 15)

The control parameter decision unit 15 obtains from the control parameter evaluation unit 5, an area evaluation result D1a and a building evaluation result D1b. Then, the control parameter decision unit 15 presents the control designer with the area evaluation result D1a and the building evaluation result D1b.

In order to allow the control designer to decide the control parameter 2 to be set to the central monitoring device 200 and the device 300, the control parameter decision unit 15 outputs, for example, a display screen which enables the control designer to browse the area evaluation result D1a and the building evaluation result D1b as well as the usage purpose of the area and the layout of the area. Specifically, the control parameter decision unit 15 outputs the display screen in a tabular form with a specific row (for example, the top row) indicating the building evaluation result D1b, and rows each indicating the usage purpose, the layout, and the area evaluation result D1a of each area. Alternatively, the control parameter decision unit 15 may output the display screen indicating a floor map of the building, with the building evaluation result D1b indicated above the floor map, and with the usage purpose, the layout, and the area evaluation result D1a of the area indicated at a corresponding portion in the floor map. Alternatively, the control parameter decision unit 15 may display these display screens while superimposing both or one of the control parameter 2 and the predictive value 4 (the predictive value 4 of each area and the predictive value 4 of the entire building) on the display screens.

When the control designer determines that there is no problem with the area evaluation result D1a and the building evaluation result D1b, the control parameter decision unit 15 outputs the control parameter 2 to the control parameter setting unit 6 based on operation of the control designer.

On the other hand, when the control designer determines that there is a problem with at least one of the area evaluation result D1a and the building evaluation result D1b, the control parameter decision unit 15 transfers processing to the control parameter input unit 11 based on operation of the control designer.

The control designer repeats the above operation until the area evaluation result D1a and the building evaluation result D1b without any problem are obtained or another termination condition is satisfied.

The control parameter input unit 11 may present the control designer with the control parameter 2 for which the area evaluation result D1a and the building evaluation result D1b have not been generated among a plurality of control parameters 2, as a new control parameter 2.

The control parameter decision unit 15 is equivalent to a display unit.

(Simulator 3)

As illustrated in FIG. 3, the simulator 3 includes a prediction unit 31, a basic model 32, and a device model 33.

Details of each will be described below.

(Prediction Unit 31)

The prediction unit 31 calculates the predictive value 4 of the entire building and the predictive value 4 of each area, using the basic model 32, the device model 33, and the control parameter 2. As described above, the predictive value 4 includes an energy value 41 and an environmental value 42.

The prediction unit 31 includes an external heat load calculation unit 311, an internal heat load calculation unit 312, an air conditioning control prediction unit 313, a CO₂ concentration calculation unit 314, a ventilation control prediction unit 315, an illuminance calculation unit 316, and a lighting control prediction unit 317.

The external heat load calculation unit 311 calculates an external heat load, using the basic model 32.

The internal heat load calculation unit 312 calculates an internal heat load, using the basic model 32.

The air conditioning control prediction unit 313 calculates the predictive values (the energy value 41 and the environmental value 42) for each area in a case where the air conditioner 301 operates according to the control parameter 2, using the basic model 32, the device model 33, the control parameter 2 set to each area, the external heat load calculated by the external heat load calculation unit 311, and the internal heat load calculated by the internal heat load calculation unit 312. Further, the air conditioning control prediction unit 313 calculates the predictive value of the entire building by adding up the predictive value of each area.

The CO₂ concentration calculation unit 314 calculates CO 2 concentration in a case where the ventilation device 302 does not operate, using the basic model 32.

The ventilation control prediction unit 315 calculates the predictive values (the energy value 41 and the environmental value 42) for each area in a case where the ventilation device 302 operates according to the parameter 2, using the basic model 32, the device model 33, the control parameter 2 set to each area, and the CO₂ concentration calculated by the CO₂ concentration calculation unit 314. Further, the ventilation control prediction unit 315 calculates the predictive value of the entire building by adding up the predictive value of each area.

The illuminance calculation unit 316 calculates illuminance in a case where the lightning device 303 does not operate, using the basic model 32.

The lighting control prediction unit 317 calculates the predictive values (the energy value 41 and the environmental value 42) for each area in a case where the lightning device 303 operates according to the control parameter 2, using the basic model 32, the device model 33, the control parameter 2 set to each area, and the illuminance calculated by the illuminance calculation unit 316. Further, the lighting control prediction unit 317 calculates the predictive value of the entire building by adding up the predictive value of each area.

Existing prediction software may be used for processing of the prediction unit 31. For example, WEBPRO, EnergyPlus, or BEST may be used for the processing of the prediction unit 31. Alternatively, modeling software may be used for the processing of the prediction unit 31. For example, Modelica, Matlab, or Python can be used as the modeling software.

(Basic Model 32)

The basic model 32 is a model used by the prediction unit 31.

The basic model 32 includes a weather forecast model 321, a building model 322, a device specification model 323, and a presence-in-room model 324.

The weather forecast model 321 is data or a prediction equation for calculating a past, present, or future weather condition.

The building model 322 is building frame attribute information indicating a building frame attribute of the building. The building model 322 indicates, specifically, the building frame attribute such as wall thickness, wall material, or wall height of a building frame.

The device specification model 323 is device specification information indicating a specification of the device 300. The device specification model 323 indicates, specifically, the specification such as rated electric power, or a Coefficient Of Performance (COP) of the device 300.

The presence-in-room model 324 is usage status information indicating usage status of each area. The presence-in-room model 324 indicates, specifically, the number of people in a room or a presence-in-room rate of each area.

Input data of a model such as Building Information Modeling (BIM) or WEBPRO may be used as the building model 322.

Alternatively, the presence-in-room model 324 may be time-series data, or may be a mathematical model that responds with the number of people occupying room or the presence-in-room rate when time is given.

(Device Model 33)

The device model 33 is a model that represents the device 300.

The device model 33 includes an air conditioning model 331, a ventilation model 332, and a lighting model 333.

The air conditioning model 331 is a model that represents the air conditioner 301.

The ventilation model 332 is a model that represents the ventilation device 302.

The lighting model 333 is a model that represents the lightning device 303.

Each of the air conditioning control prediction unit 313, the ventilation control prediction unit 315, and the lighting control prediction unit 317 predicts changes in the energy value and the environmental value due to operation of the device 300, using the device model 33.

As with the prediction unit 31, an existing prediction software module can be used, or a dedicated module may be created, as the device model 33.

(Predictive Value 4)

As illustrated in FIG. 2, the predictive value 4 includes the energy value 41 and the environmental value 42.

(Energy Value 41)

The energy value 41 includes an energy value for each area and an energy value of the entire building. The energy value 41 includes, as described above, at least one of electric power consumption by a demand device, electric power supply to the demand device, generated electric power by an energy generation device, and accumulated electric power by an energy accumulation device.

(Environmental Value 42)

The environmental value 42 includes an environmental value for each area and an environmental value of the entire building. The environmental value 42 is, as described above, a physical amount such as temperature, humidity, air volume, CO₂ concentration, or illuminance. Further, an environmental satisfaction degree such as a Predicted Mean Vote (PMV) may be used as the environmental value 42.

(Control Parameter Evaluation Unit 5)

As illustrated in FIG. 2, the control parameter evaluation unit 5 includes an area evaluation unit 51, a building evaluation unit 52, an area evaluation expression 53, and a building evaluation expression 54.

(Area Evaluation Unit 51)

The area evaluation unit 51 acquires the predictive value 4 of each area. Then, the area evaluation unit 51 evaluates for each area, the predictive value 4, using the area evaluation expression 53. Then, the area evaluation unit 51 outputs for each area, the area evaluation result D1a which is an evaluation result.

If the predictive value 4 falls within a range of the area evaluation expression 53 to be described below, the area evaluation unit 51 outputs the area evaluation result D1a indicating that the predictive value 4 is favorable. On the other hand, if the predictive value 4 does not fall within the range of the area evaluation expression 53, the area evaluation unit 51 outputs the area evaluation result D1a indicating that the predictive value 4 is not favorable. The area evaluation unit 51 may add to the area evaluation result D1a indicating that the predictive value 4 is not favorable, supplementary information indicating a degree (a numerical distance or the like) of deviation of the predictive value 4 from the area evaluation expression 53.

The area evaluation unit 51 is equivalent to a first predictive value acquisition unit and a first evaluation unit. Further, a process performed by the area evaluation unit 51 is equivalent to a first predictive value acquisition process and a first evaluation process.

(Building Evaluation Unit 52)

The building evaluation unit 52 acquires the predictive value 4 of the entire building. Then, the building evaluation unit 52 evaluates the predictive value 4 of the entire building, using the building evaluation expression 54. Then, the building evaluation unit 52 outputs the building evaluation result D1b which is an evaluation result.

If the predictive value 4 falls within a range of the building evaluation expression 54 to be described below, the building evaluation unit 52 outputs the building evaluation result D1b indicating that the predictive value 4 is favorable. On the other hand, if the predictive value 4 does not fall within the range of the building evaluation expression 54, the building evaluation unit 52 outputs the building evaluation result D1b indicating that the predictive value 4 is not favorable. The building evaluation unit 52 may add to the building evaluation result D1b indicating that the predictive value 4 is not favorable, supplementary information indicating a degree (a numerical distance or the like) of deviation of the predictive value 4 from the building evaluation expression 54.

The building evaluation unit 52 is equivalent to a second predictive value acquisition unit and a second evaluation unit. Further, a process performed by the building evaluation unit 52 is equivalent to a second predictive value acquisition process and a second evaluation process.

(Area Evaluation Expression 53)

The area evaluation expression 53 is an evaluation expression for the predictive value 4 that represents a customer's request for each area. The area evaluation expression 53 is equivalent to a partial evaluation criterion.

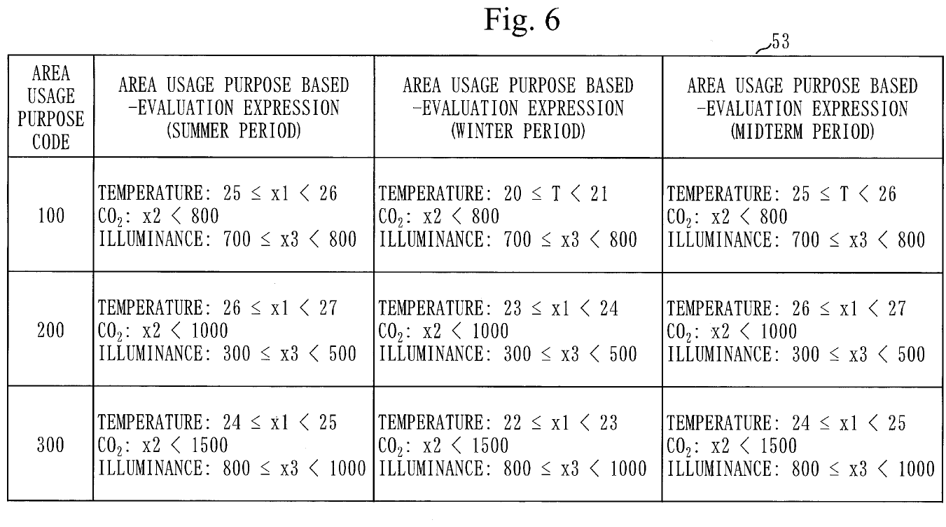

FIG. 6 illustrates an example of the area evaluation expression 53.

The area evaluation expression 53 includes an area usage purpose code and an area usage purpose based-evaluation expression. The area usage purpose code is a code that represents area usage purpose. The area usage purpose based-evaluation expression is an expression that represents the customer's request.

In the example of FIG. 6, the area usage purpose based-evaluation expression is defined for each period. That is, in the example of FIG. 6, three are defined, which are the area usage purpose based-evaluation expression (summer period), the area usage purpose based-evaluation expression (winter period), and the area usage purpose based-evaluation expression (midterm period). Each of the evaluation expressions for each area usage purpose in FIG. 6 indicates a range of the customer's request for temperature, CO₂, or illuminance.

The area evaluation expression 53 may indicate a value other than temperature, humidity, CO₂, and illuminance as long as the value is included in the predictive value 4.

For example, the area evaluation expression 53 may indicate an energy value, a PMV, humidity, or the like.

(Building Evaluation Expression 54)

The building evaluation expression 54 is an evaluation expression for the predictive value 4, which represents a customer's request for the entire building. The building evaluation expression 54 is equivalent to an overall evaluation criterion.

The building evaluation expression 54 may be the same evaluation expression as the area evaluation expression 53, or may be a different type of evaluation expression that represents the customer's request for the entire building.

[Hardware Configuration Diagram]

Next, a hardware configuration example of the device control design apparatus 100 will be described.

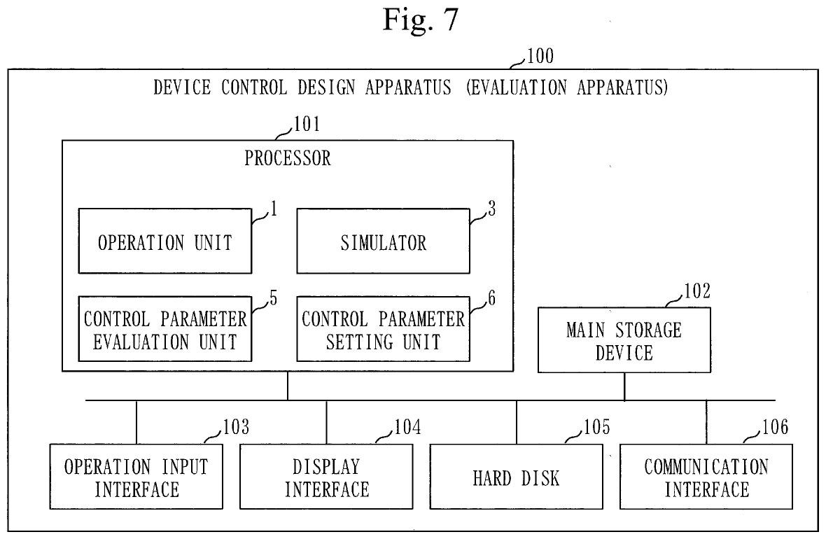

FIG. 7 illustrates a hardware configuration example of the device control design apparatus 100 according to the present embodiment.

The device control design apparatus 100 is a computer.

The device control design apparatus 100 includes a processor 101, the main storage device 102, an operation input interface 103, a display interface 104, the hard disk 105, and a communication interface 106.

The hard disk 105 stores programs that implement functions of the operation unit 1, the simulator 3, the control parameter evaluation unit 5, and the control parameter setting unit 6.

These programs are loaded from the hard disk 105 into the main storage device 102. Then, the processor 101 executes these programs and performs operation of the operation unit 1, the simulator 3, the control parameter evaluation unit 5, and the control parameter setting unit 6 to be described below.

FIG. 7 schematically illustrates a state in which the processor 101 executes the programs that implement the functions of the operation unit 1, the simulator 3, the control parameter evaluation unit 5, and the control parameter setting unit 6.

The control parameter 2, the predictive value 4, the area usage purpose information 12, the layout information 13, the basic model 32, and the device model 33 are stored in the main storage device 102 or the hard disk 105.

The operation input interface 103 receives operation from the control designer.

The display interface 104 is used for information presentation to the control designer.

The communication interface 106 is used for communication with the central monitoring device 200 and the device 300.

***Description of Operation***

Next, an operational example of the device control design apparatus 100 will be described.

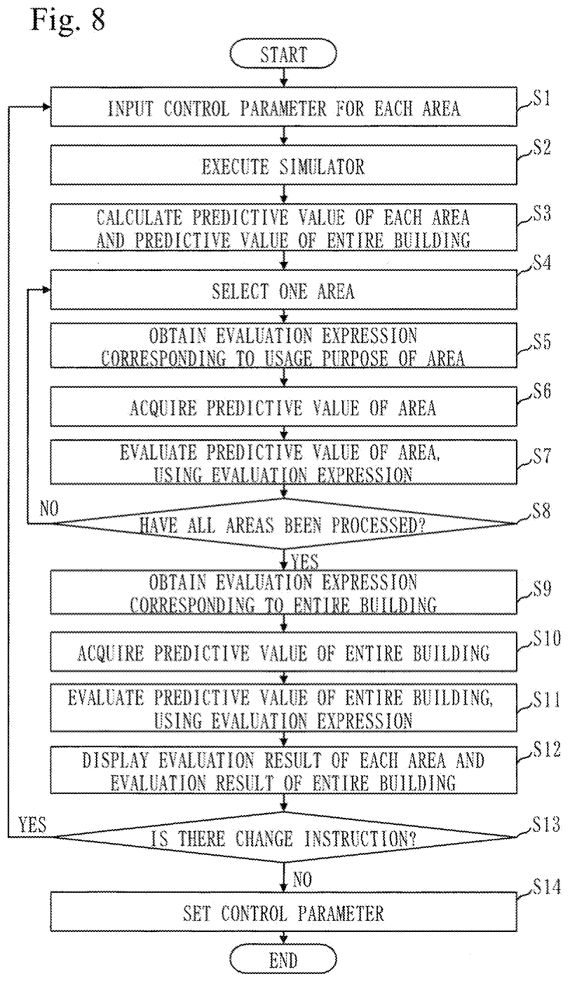

FIG. 8 is a flowchart illustrating an operational example of the device control design apparatus 100 according to the present embodiment.

The operational example of the device control design apparatus 100 will be described with reference to FIG. 8.

(Step S1)

First, in step S1, the control parameter input unit 11 inputs the control parameter 2 for each area from the control designer. When the input of the control parameter 2 is completed, the control parameter input unit 11 instructs the simulator execution unit 14 to execute the simulator 3.

(Step S2)

Next, in step S2, the simulator execution unit 14 executes the simulator 3. Specifically, the simulator execution unit 14 outputs the control parameter 2 to the simulator 3.

(Step S3)

Next, in step S3, the prediction unit 31 of the simulator 3 calculates the predictive value of each area and the predictive value of the entire building.

Specifically, the prediction unit 31 calculates the predictive value of each area in a case where the device 300 operates according to the control parameter 2, using the basic model 32, the device model 33, and the control parameter 2. Then, the prediction unit 31 calculates the predictive value of the entire building by adding up the predictive value of each area.

Then, the prediction unit 31 outputs to the control parameter evaluation unit 5, the calculated predictive value of each area and the calculated predictive value of the entire building, as the predictive value 4.

(Step S4)

Next, in step S4, the area evaluation unit 51 of the control parameter evaluation unit 5 selects one area in the bulling.

(Step S5)

Next, in step S5, the area evaluation unit 51 obtains from the area evaluation expression 53, the area usage purpose based-evaluation expression corresponding to the usage purpose of the selected area.

When there is the area usage purpose based-evaluation expression for each period as illustrated in FIG. 6, the area evaluation unit 51 determines which of the summer period, the winter period and the midterm period the present corresponds to, and obtains the area usage purpose based-evaluation expression for the period corresponding to the present.

(Step S6)

Next, in step S6, the area evaluation unit 51 acquires from the predictive value 4, the predictive value of the selected area.

(Step S7)

Next, in step S7, the area evaluation unit 51 evaluates the predictive value acquired in step S6, using the area usage purpose based-evaluation expression obtained in step S5.

Then, the area evaluation unit 51 generates the area evaluation result D1a indicating the evaluation result.

(Step S8)

Next, in step S8, the area evaluation unit 51 determines whether or not the evaluation of the predictive value for all areas in the building has been completed. When the evaluation of the predictive value for all areas has been completed, processing proceeds to step S9. On the other hand, when there is an area for which the evaluation of the predictive value has not been completed, processing returns to step S4, and the area evaluation unit 51 selects the next area.

(Step S9)

In Step S9, the building evaluation unit 52 obtains the building evaluation expression 54.

(Step S10)

Next, in step S10, the building evaluation unit 52 acquires from the predictive value 4, the predictive value of the entire building.

(Step S11)

Next, in step S11, the building evaluation unit 52 evaluates the predictive value of the entire building, using the building evaluation expression 54.

Then, the building evaluation unit 52 generates the building evaluation result D1b indicating the evaluation result.

(Step S12)

Next, in step S12, the control parameter decision unit 15 obtains the area evaluation result D1a and the building evaluation result D1b, and displays the area evaluation result D1a and the building evaluation result D1b.

(Step S13)

Next, in step S13, the control parameter decision unit 15 determines whether or not there is a change instruction on the control parameter 2 from the control designer.

As described above, the control designer determines whether or not there is a problem with the current control parameter 2 by checking the area evaluation result D1a and the building evaluation result D1b. When there is the problem with the current parameter 2, the control designer inputs to the control parameter decision unit 15, the change instruction on the control parameter 2.

When the change instruction is input, the control parameter decision unit 15 outputs the change instruction to the control parameter input unit 11. Then, the control parameter input unit 11 inputs a new control parameter 2 from the control designer (step S1). After that, processing of step S2 and thereafter is performed for the new control parameter 2.

On the other hand, when the change instruction is not input, processing proceeds to step S14.

(Step S14)

In step S14, the control parameter setting unit 6 sets the decided control parameter 2 to the central monitoring device 200 and/or the device 300.

***Description of Effects of Embodiment***

As described above, the area evaluation result D1a and the building evaluation result D1b are used in the present embodiment. Therefore, according to the present embodiment, it is possible to design device control that satisfies a customer's request while balancing in both of an entire building and each area in the building.

Further, the control parameter decision unit 15 displays an evaluation result for each area in the building. Therefore, the present embodiment facilitates checking whether or not a customer's request is satisfied in each area used by a tenant or an area user, even if a building has a plurality of tenants or a plurality of area users.

Further, the control parameter decision unit 15 can perform a comparison among the predictive value 4, the area evaluation result D1a, and the building evaluation result D1b. Therefore, the present embodiment can suggest an area whose control parameter needs to be reviewed, when the building evaluation result D1b is not favorable.

### Embodiment 2

In the present embodiment, differences from Embodiment 1 will be mainly described.

Matters not described below are the same as those in Embodiment 1.

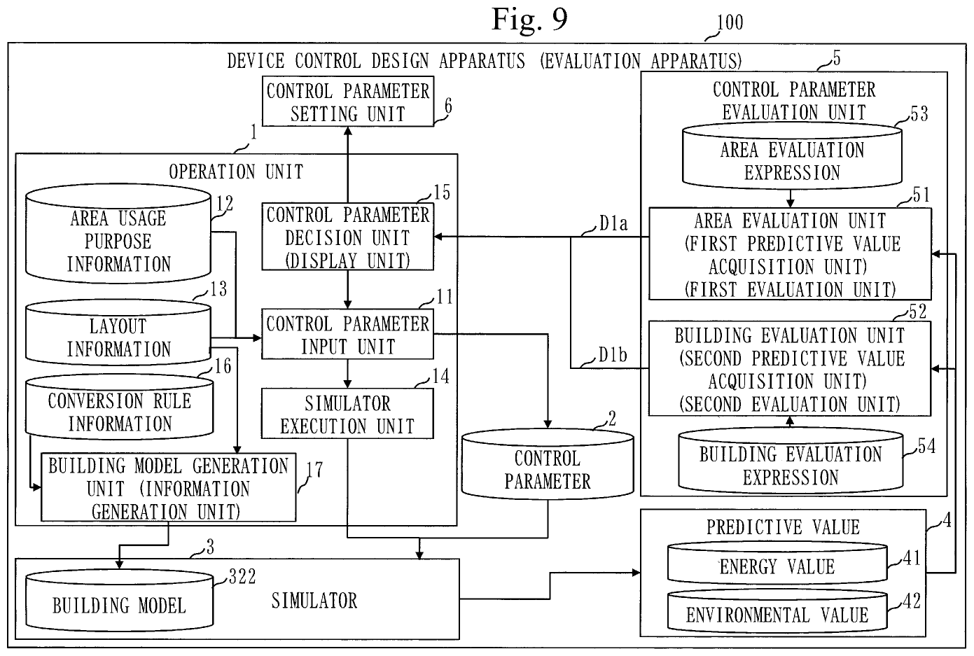

FIG. 9 illustrates a functional configuration example of the device control design apparatus 100 according to the present embodiment.

Compared with FIG. 2, conversion rule information 16 and a building model generation unit 17 are added in FIG. 9.

The conversion rule information 16 and the building model generation unit 17 will be mainly described below.

(Conversion Rule Information 16)

The conversion rule information 16 indicates a conversion rule for converting the layout of the building indicated in the layout information 13 into the building model 322 of the basic model 32. The conversion rule information 16 indicates, for example, a conversion rule for converting area usage purpose into wall thickness, wall material, or the like of a building frame, or a conversion rule for converting GIS coordinates into wall length, wall height, or the like of a building frame.

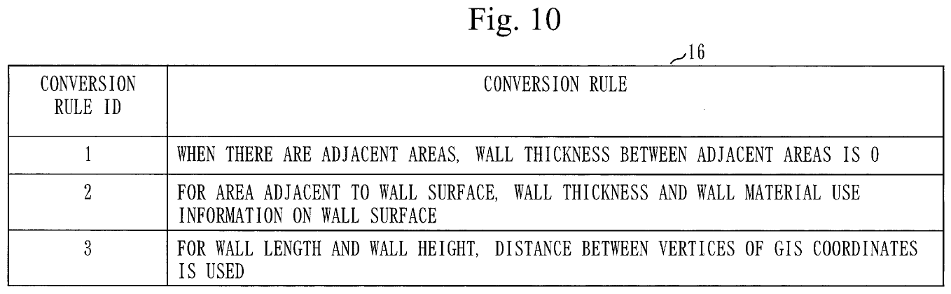

FIG. 10 illustrates an example of the conversion rule information 16. The conversion rule information 16 defines rules for deciding wall thickness, wall material, wall length and wall height of the building frame, for each area indicated in the layout information 13.

The layout information 13 may be generated by the BIM, or may be generated by other software. In such a case, the conversion rule information 16 describes a rule to convert the layout information 13 generated by the BIM or the other software into the building model 322.

(Building Model Generation Unit 17)

According to operation of the control designer or when a prescribed condition is met, the building model generation unit 17 converts the layout information 13 into the building model 322 which is building frame attribute information, with reference to the conversion rule information 16. That is, the building model generation unit 17 generates the building model 322 which is the building frame attribute information by converting the layout information 13. Then, the building model generation unit 17 stores the building model 322 into the basic model 32.

Here, the prescribed condition is, for example, arrival of a regular execution schedule, update of the conversion rule information 16 or the layout information 13, or activation of the device control design apparatus 100. The building model generation unit 17 is equivalent to an information generation unit.

In the present embodiment, the prediction unit 31 generates the predictive value 4, using the building model 322 generated by the building model generation unit 17. Then, as described in Embodiment 1, the control parameter evaluation unit 5 performs the evaluation of the predictive value 4.

As described above, according to the present embodiment, it is possible to obtain from layout information, a building model necessary for simulation. Therefore, according to the present embodiment, a control designer can acquire a predictive value in a unit of area, based on the layout information, even for a building for which the building model is not given since the building is not yet fully constructed. As a result, as with Embodiment 1, it is possible to accurately evaluate the predictive value in the unit of area, and decide a control parameter of a device in the building.

### Embodiment 3

In the present embodiment, differences from Embodiment 1 will be mainly described.

Matters not described below are the same as those in Embodiment 1.

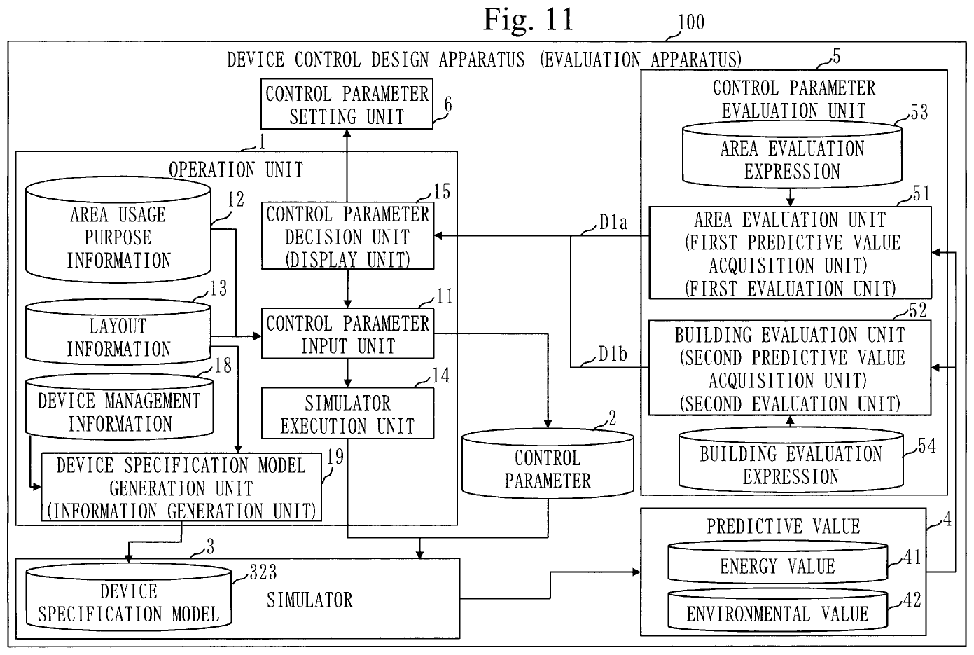

FIG. 11 illustrates a functional configuration example of the device control design apparatus 100 according to the present embodiment.

Compared with FIG. 2, device management information 18 and a device specification model generation unit 19 are added in FIG. 11.

The device management information 18 and the device specification model generation unit 19 will be mainly described below.

(Device Management Information 18)

The device management information 18 is information for managing the device 300 in the building.

The device management information 18 is, for example, device classification information, device model number information, device serial number information, device installation position information, a photograph of a device installation status, or the like.

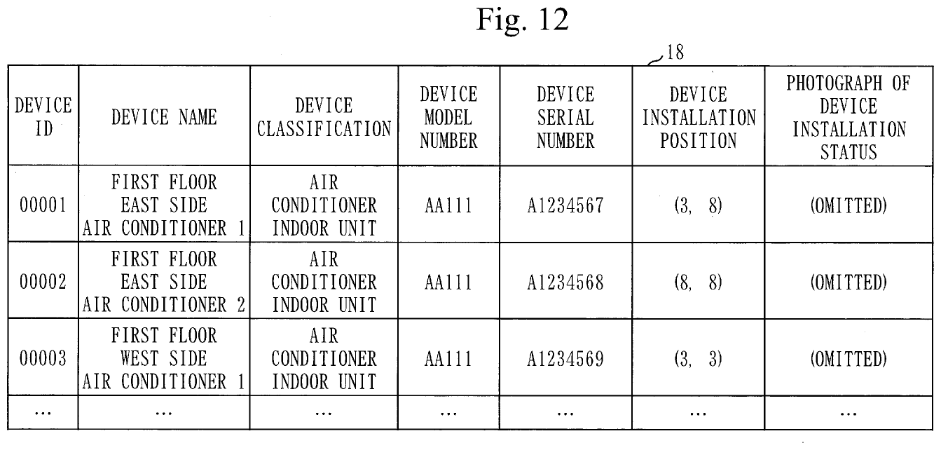

FIG. 12 illustrates an example of the device management information 18.

The device management information 18 stores a device ID, a device name, a device classification, a device model number, a device serial number, a device installation position, and a photograph of device installation status for each device 300 in the building.

The device management information 18 may be stored in another system such as a Building Management System (BMS) or a device management ledger.

The device specification model generation unit 19 can obtain the device management information 18 through an Application Programming Interface (API) or other interfaces, as appropriate. Further, the device specification model generation unit 19 can also obtain the device management information 18 in a format such as Comma Separated Values (CSV).

(Device Specification Model Generation Unit 19)

According to operation of the control designer or when a prescribed condition is met, the device specification model generation unit 19 converts the layout information 13 into the device specification model 323 which is device specification information, with reference to the device management information 18. That is, the device specification model generation unit 19 generates the device specification model 323 which is the device specification information by converting the layout information 13. Then, the device specification model generation unit 19 stores the device specification model 323 into the basic model 32.

Here, the prescribed condition is, for example, arrival of a regular execution schedule, update of the device management information 18 or the layout information 13, or activation of the device control design apparatus 100.

The device specification model generation unit 19 is equivalent to an information generation unit.

The device specification model 323 represents a relation between the device 300 and an area. The device specification model generation unit 19 specifies the device 300 installed in each area, based on layout coordinates of the area (a relative position of each area in the building) of the layout information 13 and a relative position of each device 300 in the building indicated in the device installation position of the device management information 18.

Then, the device specification model generation unit 19 generates the device specification model 323 indicating the device 300 installed in each area. Further, the device specification model generation unit 19 may generate the device specification model 323 indicating influence on the device 300 installed in an area, from the device 300 installed in an adjacent area.

In the present embodiment, the prediction unit 31 generates the predictive value 4, using the device specification model 323 generated by the device specification model generation unit 19. As described in Embodiment 1, the control parameter evaluation unit 5 performs the evaluation of the predictive value 4.

As described above, according to the present embodiment, it is possible to obtain from layout information, a device specification model necessary for simulation. Therefore, according to the present embodiment, a control designer can set a control parameter of a device, specifying an area. Then, the control designer can design more detailed device control which enables only a device corresponded to the area to be controlled.

### Embodiment 4

Differences from Embodiment 3 will be mainly described in the present embodiment.

Matters not described below are the same as those in Embodiment 3.

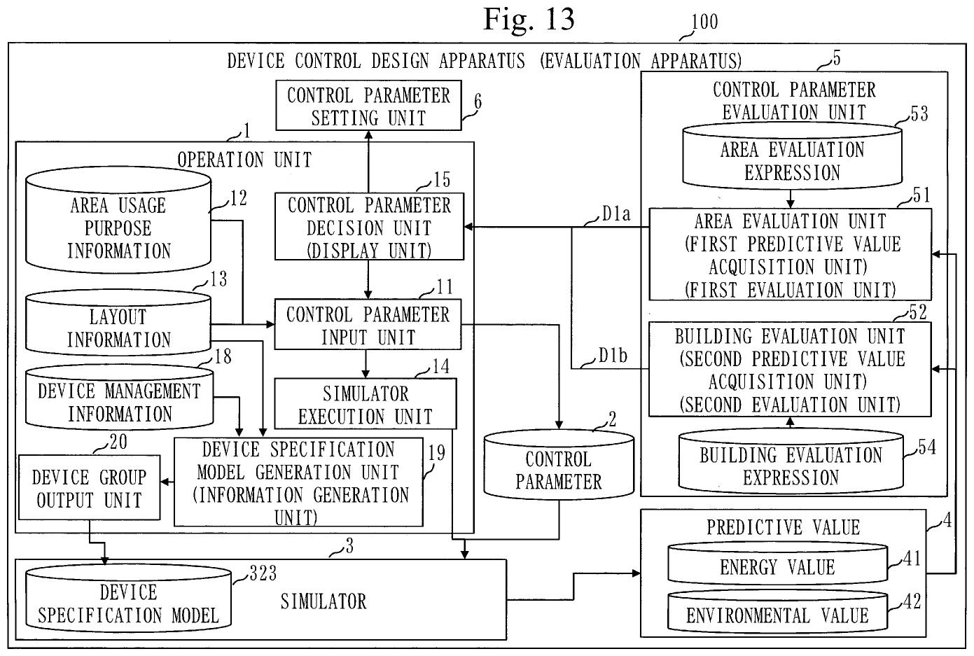

FIG. 13 illustrates a functional configuration example of the device control design apparatus 100 according to the present embodiment.

Compared with FIG. 11, a device group output unit 20 is added in FIG. 13.

The device group output unit 20 will be mainly described below.

(Device Group Output Unit 20)

According to operation of the control designer or when a prescribed condition is met, the device group output unit 20 groups the device 300, with reference to the device specification model 323 output by the device specification model generation unit 19. Then, the device group output unit 20 adds for each group, device group information indicating a device 300 that belongs to each group, to the device specification model 323, and stores the device specification model 323 to which the device group information is added, into the basic model 32.

Here, the prescribed condition is, for example, arrival of a regular execution schedule, update of the device management information 18 or the layout information 13, or activation of the device control design apparatus 100.

The device group output unit 20 groups the device 300 according to a feature of the device 300. For example, the device group output unit 20 groups the air conditioners 301 installed on the east side of one building, into the same group. Further, the device group output unit 20 groups the air conditioners 301 connected to a common outdoor unit by pipes into the same group.

A definition of the feature of the device 300 considered when grouping is stored in the device management information 18. Further, the control designer can use an input screen to register the definition of the feature of the device 300 considered when grouping.

In the present embodiment, the control parameter 2 is set for each group of the devices 300. Therefore, the prediction unit 31 calculates for each area, a predictive value predicted to be measured in a case where each device 300 operates according to the control parameter 2 set to a group to which each device 300 belongs.

Then, the area evaluation unit 51 performs the evaluation of the predictive value 4 calculated such as above by the prediction unit 31.

As described above, according to the present embodiment, it is possible to set a control parameter in a unit of group of the devices 300. Accordingly, it is possible to reduce design man-hours of a design controller (for example, an engineer). Further, as to a device to which uniformity is required such as a lighting device, it is possible to ensure the uniformity by employing a common control parameter for a plurality of devices.

### Embodiment 5

Differences from Embodiment 1 will be described in the present embodiment.

Matters not described below are the same as those in Embodiment 1.

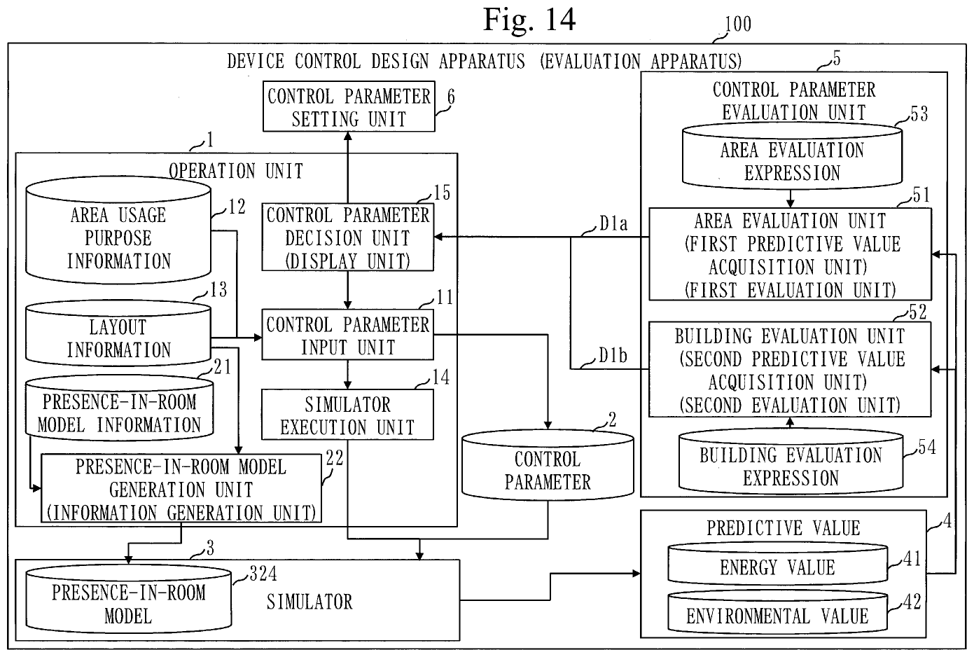

FIG. 14 illustrates a functional configuration example of the device control design apparatus 100 according to the present Embodiment 5.

Compared with FIG. 2, presence-in-room model information 21 and a presence-in-room model generation unit 22 are added in FIG. 14.

The presence-in-room model information 21 and the presence-in-room model generation unit 22 will be mainly described below.

(Presence-In-Room Model Information 21)

The presence-in-room model information 21 indicates a presence-in-room model for each usage purpose of an area. For example, the presence-in-room model for an area having a usage purpose (Focus) of concentration, indicates an increase in the number of people from morning to noon, a decrease in the number of people during lunch break, an increase in the number of people after lunch break, and a decrease in the number of people from noon to evening. Further, the presence-in-room model for an area having a usage purpose (Meeting) of a conference, indicates that no people is present before working hours, during lunch break, and after working hours, and the number of people present during hours in between is almost the same.

Further, as the presence-in-room model information 21, a presence-in-room model for each usage purpose used in WEBPRO can be utilized.

(Presence-In-Room Model Generation Unit 22)

According to operation of the control designer or when a prescribed condition is met, the presence-in-room model generation unit 22 obtains the area usage purpose information 12. Then, the presence-in-room model generation unit 22 obtains for each area, the presence-in-room model information 21 on the corresponding usage purpose, and selects the presence-in-room model for each area. Then, the presence-in-room model generation unit 22 stores the presence-in-room model selected for each area, as the presence-in-room model 324 of the basic model 32.

Thus, the presence-in-room model generation unit 22 generates the presence-in-room model 324 which is usage status information, and is equivalent to an information generation unit.

Here, the prescribed condition is, for example, arrival of a regular execution schedule, update of the device management information 18 or the presence-in-room model information 21, and activation of the device control design apparatus 100.

In the present embodiment, the prediction unit 31 calculates the predictive value for each area, using the presence-in-room model 324 generated such as above.

Then, the area evaluation unit 51 performs the evaluation of the predictive value 4 calculated such as above by the prediction unit 31.

As described above, according to the present embodiment, it is possible to obtain from the area usage purpose information 12, a presence-in-room model necessary for simulation. Therefore, according to the present embodiment, in addition to designing device control based on a presence-in-room model uniformly directed to an entire building, a control designer can design device control, giving consideration to a difference in the number of people of each area depending on area usage purposes.

### Embodiment 6

Differences from Embodiment 1 will be mainly described.

Matters not described below are the same as those in Embodiment 1.

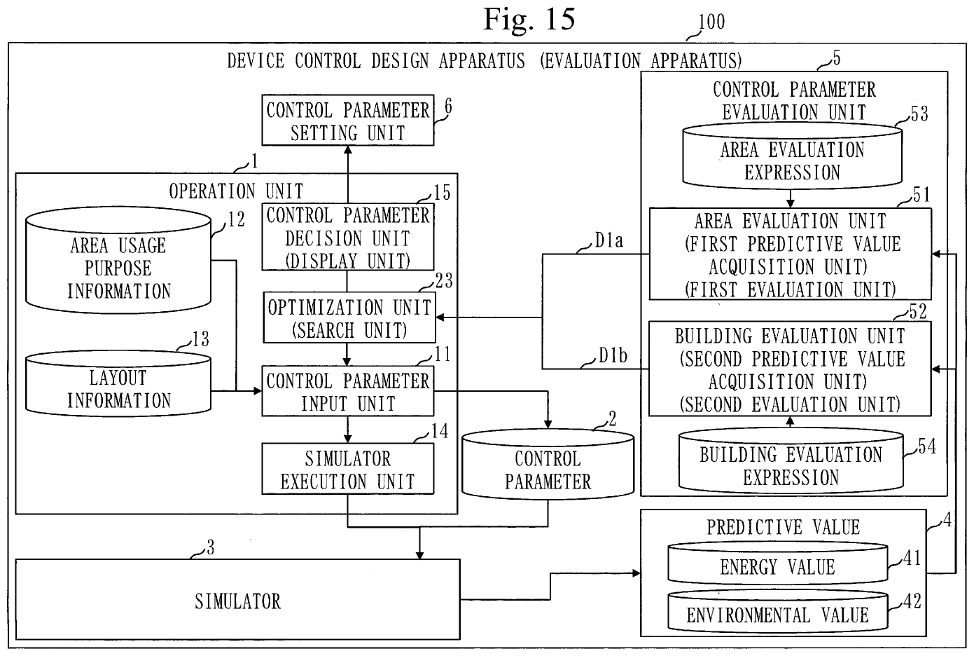

FIG. 15 illustrates a functional configuration example of the device control design apparatus 100 according to the present embodiment.

Compared with FIG. 2, an optimization unit 23 is added in FIG. 15.

The optimization unit 23 will be mainly described below.

(Optimization Unit 23)

In at least one of a case where the area evaluation unit 51 evaluates that the predictive value of any area does not conform to the corresponding area evaluation expression 53 and a case where the building evaluation unit 52 evaluates that the predictive value of the entire building does not conform to the building evaluation expression 54, the optimization unit 23 searches for a control parameter 2 (hereinafter referred to as an optimal control parameter 2) for which each of predictive values of all areas conforms to the corresponding area evaluation expression 53, and the predictive value of the entire building conforms to the building evaluation expression 54.

More specifically, the optimization unit 23 repeatedly executes the simulator 3 while changing the control parameter 2 until the optimal control parameter 2 is obtained. Then, the optimization unit 23 outputs to the control parameter decision unit 15, the optimal control parameter 2 obtained such as above. The optimal control parameter 2 may be an approximate solution or a plurality of solution candidates. For example, in a multi-objective optimization technique using genetic algorithm, Pareto solutions that satisfy a plurality of objectives are searched for, and a superior solution is selected as a solution candidate. At this time, since the superior solution may exist for each of the plurality of objectives, a plurality of pieces of solution candidates may be selected.

The optimization unit 23 obtains the area evaluation result D1a of the area evaluation unit 51 and the building evaluation result D1b of the building evaluation unit 52, and searches for an optimal solution, using these as a solution of an objective function. A variable value of the objective function is the control parameter 2. The optimization unit 23 solves the objective function with the simulator 3, and obtains the predictive value 4 used for the evaluation by the control parameter evaluation unit 5.

As described above, the optimization unit 23 may execute the simulator 3a plurality of times while changing the control parameter 2 until the solution search converges. At this time, the control designer may change the control parameter 2, using the control parameter input unit 11. Alternatively, it is possible to omit the change in the control parameter 2 using the control parameter input unit 11, by deciding the control parameter 2 to be used next, by the multi-objective optimization technique described above.

After the search for the solution is completed, the optimization unit 23 outputs the solution (the optimal control parameter 2) to the control parameter decision unit 15. Then, the control parameter decision unit 15 presents the control designer with the optimal control parameter 2.

The optimization unit 23 is equivalent to a search unit.

As described above, according to the present embodiment, it is possible to optimize a control parameter from evaluation results of both of an area and an entire building. Therefore, according to the present embodiment, a control designer can set the control parameter optimized in consideration of the evaluation results of the area and the entire building. Further, by entrusting algorithm with a solution search of the optimization unit 23, the control designer can semi-automatically obtain an optimal solution or a control parameter close to the optimal solution without manually reviewing the control parameter.

### Embodiment 7

Differences from Embodiment 1 will be mainly described.

Matters not described below are the same as those in Embodiment 1.

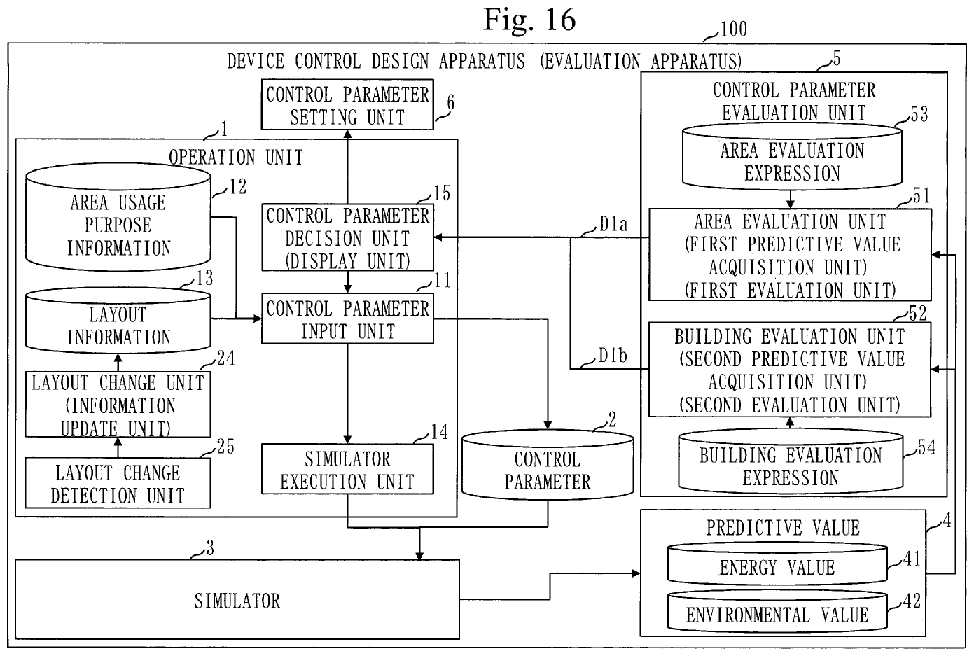

FIG. 16 illustrates a functional configuration example of the device control design apparatus 100 according to the present embodiment.

Compared with FIG. 2, a layout change unit 24 and a layout change detection unit 25 are added in FIG. 16.

The layout change unit 24 and the layout change detection unit 25 will be mainly described below.

(Layout Change Detection Unit 25)

The layout change detection unit 25 detects a layout change in one of the plurality of areas. Then, the layout change detection unit 25 notifies the layout change unit 24 of the detected layout change.

For example, the control designer inputs the latest layout of the building to the layout change detection unit 25. Then, the layout change detection unit 25 compares the current layout indicated in the layout information 13 with the latest layout, and detects the layout change.

Further, the control designer may confirm the latest layout based on an image obtained from a sensor (a temperature and humidity sensor, an illuminance sensor, a human sensor, a thermal image camera, or the like) attached to a surveillance camera or the device 300, and may input the latest layout to the layout change detection unit 25. Also in this case, the layout change detection unit 25 detects the layout change by comparing the current layout indicated in the layout information 13 with the latest layout.

(Layout Change Unit 24)

The layout change unit 24 reflects to the layout information 13, the layout change detected by the layout change detection unit 25.

The layout change unit 24 is equivalent to an information update unit.

Next, an operational example according to the present embodiment will be described.

(Case 1: a case where the control designer inputs the latest layout to the layout change detection unit 25)

When the control designer inputs the latest layout to the layout change detection unit 25, the control designer inputs information on the latest layout to the layout change detection unit 25 through an input screen. The control designer may input the information on the latest layout in any format. The layout change detection unit 25 detects the layout change by comparing the latest layout indicated in the input information from the control designer with the current layout indicated in the layout information 13. Then, the layout change detection unit 25 notifies the layout change unit 24 of the detected layout change, and the layout change unit 24 changes description of the layout information 13 so that the description of the layout information 13 conforms to the changed layout.

(Case 2: a case where the surveillance camera or the sensor is used)

When the surveillance camera or the sensor is used, a condition for detecting the layout change is set in advance. The layout change detection unit 25 determines whether or not the image obtained from the surveillance camera or the sensor satisfies the condition. When the image obtained from the surveillance camera or the sensor satisfies the condition, the layout change detection unit 25 notifies the control designer that the layout has been changed. The control designer confirms the latest layout by watching the image or by checking a drawing, and inputs the information on the latest layout to the layout change detection unit 25 through the input screen. Subsequent operation is the same as that in Case 1.

As described above, according to the present embodiment, it is possible to design a control parameter by reflecting a layout change generated during a building being practically used. Therefore, according to the present embodiment, it is possible to obtain an optimal control parameter that conforms to the latest usage status of an area even during the building being practically used.

### Embodiment 8

Differences from Embodiment 1 will be mainly described in the present embodiment.

Matters not described below are the same as those in Embodiment 1.

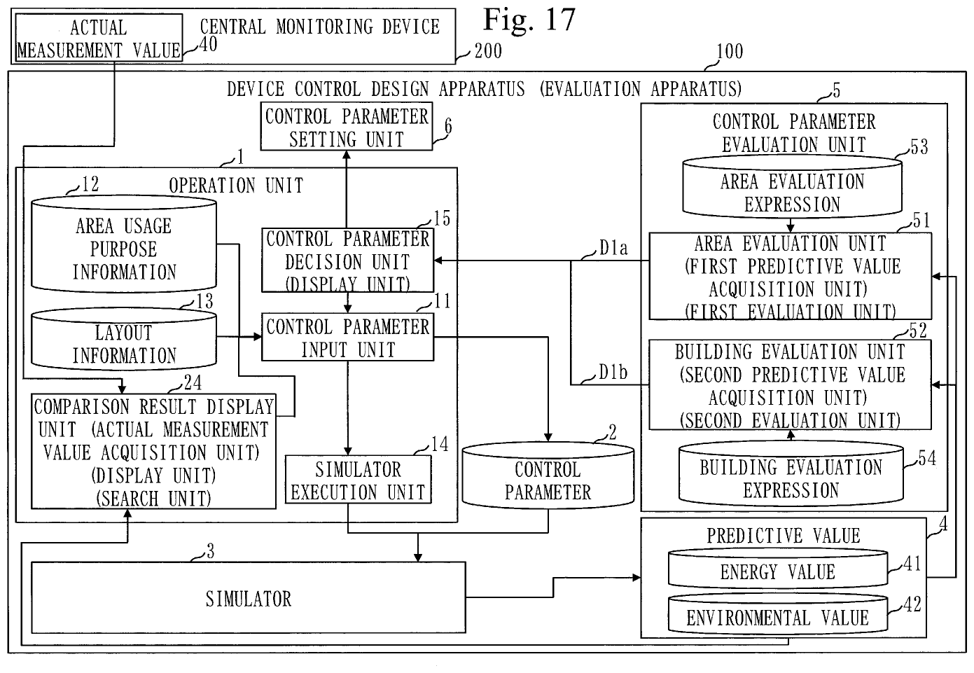

FIG. 17 illustrates a functional configuration example of the device control design apparatus 100 according to the present embodiment.

Compared with FIG. 2, a comparison result display unit 26 is added in FIG. 17.

The comparison result display unit 26 will be mainly described below.

(Comparison Result Display Unit 26)

The comparison result display unit 26 acquires an actual measurement value 40 and the predictive value 4. The actual measurement value 40 includes an actual measurement value of each area and an actual measurement value of the entire building. The actual measurement value of each area is a measurement value of each area measured when the device 300 actually operates. The actual measurement value of the entire building is a measurement value of the entire building calculated using a plurality of actual measurement values of the plurality of areas. The actual measurement value of the entire building is equivalent to an overall actual measurement value. When there is no need to distinguish between the actual measurement value of each area and the actual measurement value of the entire building, both are collectively referred to as the actual measurement value 40.

The comparison result display unit 26 may acquire the actual measurement value 40 from the central monitoring device 200 as illustrated in FIG. 17, or may acquire the actual measurement value 40 from the device 300.

The comparison result display unit 26 displays the actual measurement value of each area and the predictive value of each area. Further, the comparison result display unit 26 displays the actual measurement value (the overall actual measurement value) of the entire building and the predictive value (the overall predictive value) of the entire building.

The comparison result display unit 26 may display the actual measurement value 40 and the predictive value 4, in any way that can indicate a difference between the actual measurement value 40 and the predictive value 4, like a table, a graph, an icon. For example, the comparison result display unit 26 may display the actual measurement value 40 and the predictive value 4 as time-series data, in a graph format in which the vertical axis indicates a value and the horizontal axis indicates a time. Displaying such as above makes clear the difference between the actual measurement value 40 and the predictive value 4. The comparison result display unit 26 displays the actual measurement value 40 and the predictive value 4 in comparison, so that the control designer can visually recognize the difference between the actual measurement value and the predictive value in terms of an energy value (an amount of electric power consumption, an amount of generated electric power, or the like), and the difference between the actual measurement value and the predictive value in terms of an environmental value (temperature, humidity, CO₂ concentration, illuminance, PMV, or the like).

If the control designer determines that a change in the control parameter 2 is necessary after confirming a display result of the comparison result display unit 26, the control designer may specify a new control parameter 2 to the control parameter input unit 11.

Further, the comparison result display unit 26 may execute the search for the control parameter 2 independently from operation of the control designer.

That is, in at least one of a case where the difference between the predictive value and the actual measurement value is equal to or greater than a first threshold value in any area, and a case where the difference between the predictive value of the entire building and the actual measurement value of the entire building is equal to or greater than a second threshold value, the comparison result display unit 26 may search for the control parameter 2 such that the difference between the predictive value and the actual measurement value is less than the first threshold value in all areas, and the difference between the predictive value of the entire building and the actual measurement value of the entire building is less than the second threshold value. The search by the comparison result display unit 26 is performed by the same method as the search by the optimization unit 23 in Embodiment 6. The first threshold value and the second threshold value can be arbitrarily decided by, for example, the control designer.

The comparison result display unit 26 is equivalent to an actual measurement value acquisition unit, a display unit, and a search unit.

As described above, according to the present embodiment, it is possible to display a difference between a predictive value and an actual measurement value during a building being practically used. Therefore, according to the present embodiment, a control designer can notice the difference between the predictive value and the actual measurement value early during the building being practically used, and confirm or redesign a control parameter.

Embodiments 1 to 8 have been described above and two or more of these embodiments may be implemented in combination.

Alternatively, one of these embodiments may be partially implemented.

Alternatively, two or more of these embodiments may be partially implemented in combination.

Further, the configurations and the procedures described in these embodiments may be modified as necessary.

***Supplementary Description of Hardware Configuration***

Finally, a supplementary description of a hardware configuration of the device control design apparatus 100 will be given.

The processor 101 illustrated in FIG. 7 is an Integrated Circuit (IC) that performs processing.

The processor 101 is a Central Processing Unit (CPU), a Digital Signal Processor (DSP), or the like.

The main storage device 102 illustrated in FIG. 7 is a Random Access Memory (RAM).

The device control design apparatus 100 may include a Read Only Memory (ROM) and a flash memory, in place of the hard disk 105 illustrated in FIG. 7.

The operation input interface 103 illustrated in FIG. 7 is, for example, a mouse, a keyboard, or the like.

The display interface 104 illustrated in FIG. 7 is, for example, a display.

The communication interface 106 illustrated in FIG. 7 is an electronic circuit that executes a communication process for data.

The communication interface 106 is, for example, a communication chip or a Network Interface Card (NIC).

Further, the hard disk 105 stores an Operating System (OS).

Then, at least a part of the OS is executed by the processor 101.

While executing at least the part of the OS, the processor 101 executes programs that implement functions of the operation unit 1, the simulator 3, the control parameter evaluation unit 5, and the control parameter setting unit 6.

By the processor 101 executing the OS, task management, memory management, file management, communication control, and the like are performed.

Further, at least one of information, data, a signal value, and a variable value indicating results of processes of the operation unit 1, the simulator 3, the control parameter evaluation unit 5, and the control parameter setting unit 6 is stored in at least one of the main storage device 102, the hard disk 105, and a register and a cache memory in the processor 101.

Further, the programs that implement the functions of the operation unit 1, the simulator 3, the control parameter evaluation unit 5, and the control parameter setting unit 6 may be stored in a portable recording medium such as a magnetic disk, a flexible disk, an optical disc, a compact disc, a Blu-ray (registered trademark) disc, or a DVD. Then, the portable recording medium storing the programs that implement the functions of the operation unit 1, the simulator 3, the control parameter evaluation unit 5, and the control parameter setting unit 6, may be distributed.

Further, “unit” of each of the operation unit 1, the control parameter evaluation unit 5, and the control parameter setting unit 6 may be replaced with “circuit”, “step”, “procedure”, “processing” or “circuitry”.

Further, the device control design apparatus 100 may be implemented by a processing circuit. The processing circuit is, for example, a logic Integrated Circuit (IC), a Gate Array (GA), an Application Specific Integrated Circuit (ASIC), or a Field-Programmable Gate Array (FPGA).

In this case, each of the operation unit 1, the simulator 3, the control parameter evaluation unit 5, and the control parameter setting unit 6 is implemented as a part of the processing circuit.

In the present description, a superordinate concept of the processor and the processing circuit is referred to as “processing circuitry”.

That is, each of the processor and the processing circuit is a specific example of the “processing circuitry”.

### REFERENCE SIGNS LIST

1: operation unit; 2: control parameter; 3: simulator; 4: predictive value; 5: control parameter evaluation unit; 6: control parameter setting unit; 11: control parameter input unit; 12: area usage purpose information; 13: layout information; 14: simulator execution unit; 15: control parameter decision unit; 16: conversion rule information; 17: building model generation unit; 18: device management information; 19: device specification model generation unit; 20: device group output unit; 21: presence-in-room model information; 22: presence-in-room model generation unit; 23: optimization unit; 24: layout change unit; 25: layout change detection unit; 26: comparison result display unit; 31: prediction unit; 32: basic model; 33: device model; 40: actual measurement value; 41: energy value; 42: environmental value; 51: area evaluation unit; 52: building evaluation unit; 53: area evaluation expression; 54: building evaluation expression; 100: device control design apparatus; 101: processor; 102: main storage device; 103: operation input interface; 104: display interface; 105: hard disk; 106: communication interface; 200: central monitoring device; 300: device; 301: air conditioner; 302: ventilation device; 303: lightning device; 311: external heat load calculation unit; 312: internal heat load calculation unit; 313: air conditioning control prediction unit; 314: CO₂ concentration calculation unit; 315: ventilation control prediction unit; 316: illuminance calculation unit; 317: lighting control prediction unit; 321: weather forecast model; 322: building model; 323: device specification model; 324: presence-in-room model; 331: air conditioning model; 332: ventilation model; 333: lighting model; 1000: device control design system; D1: evaluation result; D1a: area evaluation result; D1b: building evaluation result.

1. An evaluation apparatus comprising:
processing circuitry:
to acquire for each area of a plurality of areas, a predictive value of each area, which is predicted to be measured when a device operates in a space that includes the plurality of areas;
to acquire an overall predictive value which is a predictive value of the entire space calculated using a plurality of predictive values of the plurality of areas;
to evaluate the acquired predictive value of each area, using a partial evaluation criterion which is an evaluation criterion applied to each area;
to evaluate the acquired overall predictive value, using an overall evaluation criterion which is an evaluation criterion applied to the entire space; and
to display an evaluation result of the predictive value of each area and an evaluation result of the overall predictive value.

2. The evaluation apparatus according to claim 1, wherein
every time when a control value candidate which is a candidate for a control value of the device is set, the processing circuitry acquires for each area, the predictive value of each area that is predicted to be measured when the device operates according to the set control value candidate,
every time when the control value candidate is set, the processing circuitry acquires the overall predictive value calculated using the plurality of predictive values of the plurality of areas calculated based on the set control value candidate,
every time when the control value candidate is set, the processing circuitry evaluates the acquired predictive value of each area, and
every time when the control value candidate is set, the processing circuitry evaluates the acquired overall predictive value.

3. The evaluation apparatus according to claim 1, wherein
the processing circuitry acquires for each area, the predictive value of each area calculated using at least one of weather information indicating a weather condition of the space, frame attribute information indicating a frame attribute of the space, device specification information indicating a specification of the device, and usage status information indicating usage status of each area.

4. The evaluation apparatus according to claim 1, wherein
the processing circuitry generates frame attribute information indicating a frame attribute of the space, based on a layout of each area, and
acquires for each area, the predictive value of each area calculated using the generated frame attribute information.

5. The evaluation apparatus according to claim 1, wherein
the processing circuitry generates device specification information indicating a specification of the device, and
acquires for each area, the predictive value of each area calculated using the generated device specification information.

6. The evaluation apparatus according to claim 5, wherein
when a plurality of devices is installed in the plurality of areas, the processing circuitry specifies a device installed in each area, based on relative position of each area in the space and relative position of each device in the space, and generates device specification information indicating the device installed in each area.

7. The evaluation apparatus according to claim 1, wherein
when two or more devices are installed in two or more areas among the plurality of areas and the two or more devices are grouped into two or more groups, and when a control value candidate which is a candidate for a control value is set to each of the two or more groups, the processing circuitry acquires for each area, the predictive value of each area predicted to be measured when the two or more devices operate according to the control value candidate set to a group to which each of the two or more devices belongs.

8. The evaluation apparatus according to claim 1, wherein
the processing circuitry generates usage status information indicating usage status of each area, based on usage purpose of each area, and
acquires for each area, the predictive value of each area calculated using the generated usage status information.

9. The evaluation apparatus according to claim 2, wherein
the processing circuitry, in at least one of a case where the processing circuitry evaluates that the predictive value of any area does not conform to the corresponding partial evaluation criterion, and a case where the processing circuitry evaluates that the overall predictive value does not conform to the overall evaluation criterion, searches for a control value candidate with which the predictive values of the plurality of areas conform to the corresponding partial evaluation criterion, and with which the overall predictive value conforms to the overall evaluation criterion.

10. The evaluation apparatus according to claim 3, wherein
the processing circuitry detects a layout change in any area among the plurality of areas; and
reflects to layout information indicating layouts of the plurality of areas, the detected layout change.

11. The evaluation apparatus according to claim 1, wherein
the processing circuitry acquires for each area, an actual measurement value which is a measurement value of each area measured when the device actually operates in the space; and
displays the predictive value of each area and the acquired actual measurement value of each area.

12. The evaluation apparatus according to claim 11, wherein
the processing circuitry acquires an overall actual measurement value which is a measurement value of the entire space calculated using a plurality of actual measurement values of the plurality of areas, and
displays the overall predictive value and the acquired overall actual measurement value.

13. The evaluation apparatus according to claim 12, wherein
the processing circuitry, in at least one of a case where a difference between the predictive value and the actual measurement value is equal to or greater than a first threshold value in any area, and a case where a difference between the overall predictive value and the overall actual measurement value is equal to or greater than a second threshold value, searches for a candidate for a control value of the device, with which the difference between the predictive value and the actual measurement value is less than the first threshold value in the plurality of areas, and with which the difference between the overall predictive value and the overall actual measurement value is less than the second threshold value.

14. An evaluation method comprising:
acquiring for each area of a plurality of areas, a predictive value of each area, which is predicted to be measured when a device operates in a space that includes the plurality of areas;
acquiring an overall predictive value which is a predictive value of the entire space calculated using a plurality of predictive values of the plurality of areas;
evaluating the acquired predictive value of each area, using a partial evaluation criterion which is an evaluation criterion applied to each area;
evaluating the acquired overall predictive value, using an overall evaluation criterion which is an evaluation criterion applied to the entire space; and
displaying an evaluation result of the predictive value of each area and an evaluation result of the overall predictive value.

15. A non-transitory computer readable medium storing an evaluation program that causes a computer to execute:
a first predictive value acquisition process to acquire for each area of a plurality of areas, a predictive value of each area, which is predicted to be measured when a device operates in a space that includes the plurality of areas;
a second predictive value acquisition process to acquire an overall predictive value which is a predictive value of the entire space calculated using a plurality of predictive values of the plurality of areas;
a first evaluation process to evaluate the predictive value of each area acquired by the first predictive value acquisition process, using a partial evaluation criterion which is an evaluation criterion applied to each area;
a second evaluation process to evaluate the overall predictive value acquired by the second predictive value acquisition process, using an overall evaluation criterion which is an evaluation criterion applied to the entire space, and
a display process to display an evaluation result by the first evaluation process and an evaluation result by the second evaluation process.
